(19) United States
(12) Patent Application Publication
(10) Pub. No.: US 2026/0367197 A1
(43) Pub. Date: Nov. 19, 2026

(54) HARMONIC FILTERING FOR ANGLE SENSORS

(71) Applicant: Allegro MicroSystems, LLC, Manchester, NH (US)

(72) Inventor: Ronald Lehndorff, Mainz (DE)

(73) Assignee: Allegro MicroSystems, LLC, Manchester, NH (US)

(21) Appl. No.: 19/207,664

(22) Filed: May 14, 2025

(51) Int. Cl. G01R 33/09; H03F 3/45

(52) U.S. Cl. CPC G01R 33/091; G01R 33/098; H03F 3/45475

(57) ABSTRACT

A sensor, comprising: a first sub-circuit including a first magnetoresistance (MR) element and a second MR element; a second sub-circuit including a third MR element and a fourth MR element; a third sub-circuit including a fifth MR element and a sixth MR element; a fourth sub-circuit including a seventh MR element and an eighth MR element; a first amplifier that is coupled to a first output node of the first sub-circuit and a second output node of the second sub-circuit, the first amplifier being configured to generate a first output signal; a second amplifier that is coupled coupled to a third output node of the third sub-circuit and a fourth output node of the fourth sub-circuit, the second amplifier being configured to generate a second output signal.

### BACKGROUND

As is known, sensors are used to perform various functions in a variety of applications. Some sensors include one or more electromagnetic flux sensing elements, such as a Hall effect element, a magnetoresistive element, or a receiving coil to sense an electromagnetic flux associated with a quantity that is desired to be monitored. Sensor integrated circuits are widely used in automobile control systems and other safety-critical applications. There are a variety of specifications that set forth requirements related to permissible sensor quality levels, failure rates, and overall functional safety.

### SUMMARY

According to aspects of the disclosure, a sensor is provided, comprising: a first sub-circuit including a first magnetoresistance (MR) element and a second MR element, the first MR element and the second MR element having respective pinning directions that are separated by approximately 180 degrees, the first sub-circuit including a first output node that is situated between the first MR element and the second MR element; a second sub-circuit including a third MR element and a fourth MR element, the third MR element and the fourth MR element having respective pinning directions that are separated by approximately 180 degrees, the second sub-circuit including a second output node that is situated between the third MR element and the fourth MR element; a third sub-circuit including a fifth MR element and a sixth MR element, the fifth MR element and the sixth MR element having respective pinning directions that are separated by approximately 180 degrees, the third sub-circuit including a third output node that is situated between the fifth MR element and the sixth MR element; a fourth sub-circuit including a seventh MR element and an eighth MR element, the seventh MR element and the eighth MR element having respective pinning directions that are separated by approximately 180 degrees, the fourth sub-circuit including a fourth output node that is situated between the seventh MR element and the eighth MR element; a first amplifier having a first input terminal and a second input terminal, the first input terminal being coupled to the first output node of the first sub-circuit, the second input terminal being coupled to the second output node of the second sub-circuit, the first amplifier being configured to generate a first output signal; and a second amplifier having a third input terminal and a fourth input terminal, the third input terminal being coupled to the third output node of the third sub-circuit, the fourth input terminal being coupled to the fourth output node of the fourth sub-circuit, the second amplifier being configured to generate a second output signal, wherein the first sub-circuit, the second sub-circuit, the third sub-circuit, and the fourth sub-circuit are coupled in parallel with each other.

According to aspects of the disclosure, a sensor is provided, comprising: a first sub-circuit including a first magnetoresistance (MR) element and a second MR element, the first MR element and the second MR element having respective pinning directions that are separated by approximately 180 degrees, the first sub-circuit including a first output node that is situated between the first MR element and the second MR element; a second sub-circuit including a third MR element and a fourth MR element, the third MR element and the fourth MR element having respective pinning directions that are separated by approximately 180 degrees, the second sub-circuit including a second output node that is situated between the third MR element and the fourth MR element; a third sub-circuit including a fifth MR element and a sixth MR element, the fifth MR element and the sixth MR element having respective pinning directions that are separated by approximately 180 degrees, the third sub-circuit including a third output node that is situated between the fifth MR element and the sixth MR element; a fourth sub-circuit including a seventh MR element and an eighth MR element, the seventh MR element and the eighth MR element having respective pinning directions that are separated by approximately 180 degrees, the fourth sub-circuit including a fourth output node that is situated between the seventh MR element and the eighth MR element; a first resistor having a first terminal and a second terminal, the first terminal being coupled to the first output node of the first sub-circuit, the second terminal being coupled to a fifth output node; a second resistor having a third terminal and a fourth terminal, the third terminal being coupled to the second output node of the second sub-circuit, the fourth terminal being coupled to the fifth output node; a third resistor having a fifth terminal and a sixth terminal, the fifth terminal being coupled to the third output node of the third sub-circuit, the sixth terminal being coupled to a sixth output node; and a fourth resistor having a seventh terminal and an eighth terminal, the seventh terminal being coupled to the fourth output node of the fourth sub-circuit, the eighth terminal being coupled to the sixth output node; wherein the first sub-circuit, the second sub-circuit, the third sub-circuit, and the fourth sub-circuit are coupled in parallel with each other and arranged to form a first sensing bridge, and wherein a first output signal of the first sensing bridge is output on the fifth output node, and a second output signal of the first sensing bridge is output on the sixth output node.

According to aspects of the disclosure, a sensor is provided, comprising: a first sub-circuit including a first magnetoresistance (MR) element and a second MR element, the first MR element and the second MR element having respective pinning directions that are separated by approximately 180 degrees, the first sub-circuit including a first output node that is situated between the first MR element and the second MR element; a second sub-circuit including a third MR element and a fourth MR element, the third MR element and the fourth MR element having respective pinning directions that are separated by approximately 180 degrees, the second sub-circuit including a second output node that is situated between the third MR element and the fourth MR element; a third sub-circuit including a fifth MR element and a sixth MR element, the fifth MR element and the sixth MR element having respective pinning directions that are separated by approximately 180 degrees, the third sub-circuit including a third output node that is situated between the fifth MR element and the sixth MR element; a fourth sub-circuit including a seventh MR element and an eighth MR element, the seventh MR element and the eighth MR element having respective pinning directions that are separated by approximately 180 degrees, the fourth sub-circuit including a fourth output node that is situated between the seventh MR element and the eighth MR element; a first resistor and a first capacitor, the first resistor having a first terminal and a second terminal, the first terminal being coupled to the first output node of the first sub-circuit, the second terminal being coupled to a fifth output node, the first capacitor being coupled in parallel with the first resistor; a second resistor and a second capacitor, the second resistor having a third terminal and a fourth terminal, the third terminal being coupled to the second output node of the second sub-circuit, the fourth terminal being coupled to the fifth output node, the second capacitor being coupled in parallel with the second resistor; a third resistor and a third capacitor, the third resistor having a fifth terminal and a sixth terminal, the fifth terminal being coupled to the third output node of the third sub-circuit, the sixth terminal being coupled to a sixth output node, the third capacitor being coupled in parallel with the third resistor; and a fourth resistor and a fourth capacitor, the fourth resistor having a seventh terminal and an eighth terminal, the seventh terminal being coupled to the fourth output node of the fourth sub-circuit, the eighth terminal being coupled to the sixth output node, the fourth capacitor being coupled in parallel with the fourth resistor; wherein the first sub-circuit, the second sub-circuit, the third sub-circuit, and the fourth sub-circuit are coupled in parallel with each other and arranged to form a first sensing bridge, and wherein a first output signal of the first sensing bridge is output on the fifth output node, and a second output signal of the first sensing bridge is output on the sixth output node.

### BRIEF DESCRIPTION OF THE DRAWINGS

The foregoing features may be more fully understood from the following description of the drawings in which:

FIG. 1A is a diagram of an example of a sensing bridge, according to aspects of the disclosure;

FIG. 1B is a diagram of an example of a sensing bridge, according to aspects of the disclosure;

FIG. 1C is a diagram of an example of a sensing bridge, according to aspects of the disclosure;

FIG. 2 is a diagram of an example of a sensing bridge, according to aspects of the disclosure;

FIG. 3 is a diagram of an example of a sensing bridge, according to aspects of the disclosure;

FIG. 4 is a diagram of an example of a sensing bridge, according to aspects of the disclosure;

FIG. 5 is a diagram of an example of a sensor, according to aspects of the disclosure;

FIG. 6 is a diagram of an example of a sensor, according to aspects of the disclosure; and

FIG. 7. is a diagram illustrating aspects of the operation of the sensing bridge of FIG. 3, according to aspects of the disclosure.

### DETAILED DESCRIPTION

Position sensors often employ a sensing bridge circuit to detect a magnetic field of interest. The sensing bridge circuit may take on various topologies, such as a Wheatstone bridge or one or more half-bridge configurations. These circuits may include one or more magnetoresistive (MR) elements, such as tunneling magnetoresistance (TMR) elements, giant magnetoresistance (GMR) elements, anisotropic magnetoresistors (AMR), colossal magnetoresistors (CMR), or any other suitable type of magnetoresistor. Each MR element in the bridge may be characterized by a pinning direction. The term “pinning direction”—particularly in the context of TMR or GMR devices—refers to the fixed orientation of magnetization in one of the magnetic layers, commonly known as the pinned layer. As used herein, the combination of the topology of a sensing bridge circuit and the respective pinning directions of the MR elements, which form the bridge circuit, at different points in the topology, defines the “programming” of the sensing bridge.

Selecting the programming of a sensing bridge is a critical design choice, as it influences the bridge's ability to filter harmonic errors. Depending on the selected programming, the output of the bridge may contain certain harmonics—such as third-order harmonics—or may be free of them. Accordingly, the choice of programming can significantly impact the accuracy of the sensing bridge.

The present disclosure relates to an improved programming scheme for magnetoresistive sensing bridges, particularly in two-dimensional TMR angle sensors (or other MR sensors), that enables both high angle accuracy and a desired 180° phase relationship between signal outputs. A programming scheme known as half-bridge filter programming achieves low angle error by minimizing harmonic distortion through voltage decoupling of half bridge signals and strategic pinning direction assignments, but does not provide the 180° phase separation of half bridge signals often required in safety-critical applications. Conversely, composite bridge configurations achieve 180° phase separation but at the cost of increased angle error due to harmonic mixing. The programming scheme that is presented in this disclosure overcomes these limitations by introducing specific signal path configurations—either through active filtering using operational amplifiers or passive filtering using decoupling resistors—between multiple half-bridges (or other sub-circuits) programmed with specific pinning angles. These configurations preserve the harmonic suppression benefits of the half-bridge filter programming while producing two single-ended outputs with a 180° phase offset, thereby enhancing sensor performance without increasing die area or TMR element count.

A 180° phase offset between half-bridge outputs may be required to support safety-critical applications that demand compliance with ASIL (Automotive Safety Integrity Level) standards. Functional safety checks—such as validating that sin²+cos²=constant or verifying that pSIN=−nSIN and pCOS=−nCOS—are only valid when the corresponding positive and negative outputs are exactly 180° out of phase. In this example, pSIN and nSIN are positive and negative sine outputs of a sensing bridge, and pCOS and nCOS are positive and negative cosine outputs of another sensing bridge that is part of the same sensor as the first one. As is well-known in the art, these signals can be used to determine the angular or linear position of a rotating or moving target whose magnetic field is monitored with the sensor. Additionally, systems often use single-ended outputs directly to generate two redundant angle values from a single sensor; these values must closely match to confirm signal integrity. The half-bridge filter programming does not provide this 180° phase relation and single-ended signals don't show the high angle accuracy of the differential signal, making it unsuitable for such redundancy and safety checks. By contrast, the programming scheme presented in this disclosure provides a 180° phase relation, together with the same harmonic suppression that is available in the differential signal of half-bridge filter programming.

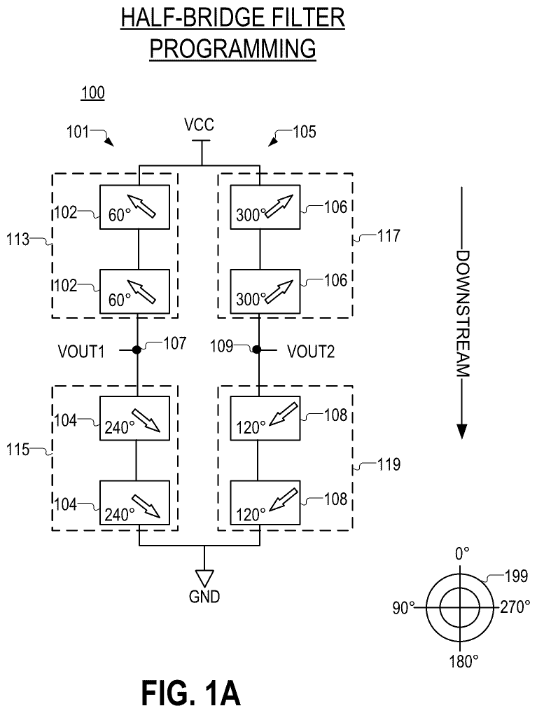

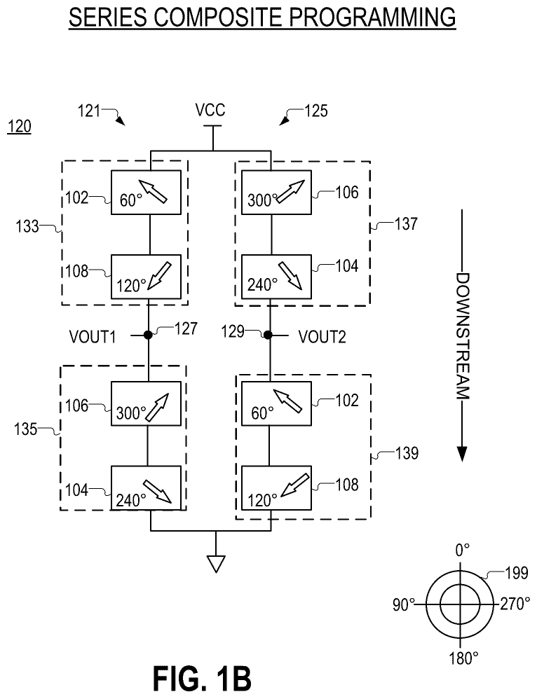

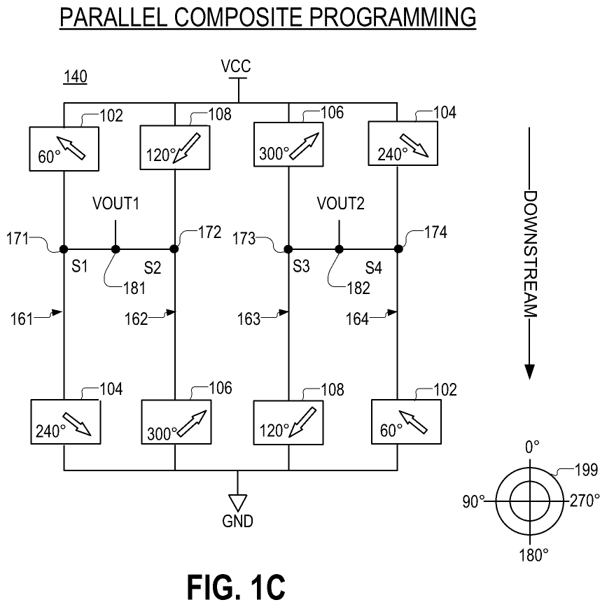

FIG. 1A illustrates a sensing bridge 100 that is configured using a half-bridge filter programming method. This sensing bridge includes two half-bridge circuits, 101 and 105, which are coupled in parallel between a voltage source and ground. Half-bridge 101 is composed of branches 113 and 115, while half-bridge 105 includes branches 117 and 119. Branch 113 connects to branch 115 at a node 107, and branch 117 connects to branch 119 at a node 109. A signal, VOUT1, is output at node 107, and another signal, VOUT2, is output at node 109. As noted above, the phase offset between signals VOUT1 and VOUT2 is 120 degrees, which may be insufficient for certain safety-critical applications.

Branch 113 includes MR elements 102 that are coupled in series with each other. Branch 115 includes MR elements 104 that are coupled in series with each other. Branch 117 includes MR elements 106 that are coupled in series with each other. Branch 119 includes MR elements 108 that are coupled in series with each other. One of MR elements 102 is coupled to another one of MR elements 104 at node 107. One of MR elements 106 is coupled to another one of MR elements 108 at node 109.

Under the nomenclature of the present disclosure, branches 113 and 119 are diagonally opposed, and branches 117 and 115 are also diagonally opposed. The term “diagonally-opposed” is used throughout the disclosure to describe two branches or MR elements in a sensing bridge that belong to first and second half-bridge circuits, wherein the first branch (or MR element) is situated upstream from a first output node in a first half-bridge at which the output of the sensing bridge is taken and the second branch (or MR element) is situated downstream from a second node in a second half-bridge from which the output of the sensing bridge is taken.

In FIGS. 1A-4, the pinning direction of each MR element—102, 104, 106, and 108—is indicated by a label within the rectangle representing that element. As shown in FIGS. 1A-C, each MR element 102 has a pinning direction of 60 degrees, each MR element 104 has a pinning direction of 240 degrees, each MR element 106 has a pinning direction of 300 degrees, and each MR element 108 has a pinning direction of 120 degrees. These pinning directions are defined within the corresponding coordinate system 199 depicted in FIGS. 1A-4.

FIG. 1A illustrates that when a sensing bridge is configured with half-bridge filter programming, the pinning directions of the MR elements in the two branches of a half bridge are separated by 180 degrees. For each MR element in any of the branches in the sensing bridge, there is a corresponding MR element in a diagonally opposed branch with a pinning direction that is separated by 60 degrees from that of the first MR element. Half of this angle is herein referred to as the “programming angle” of sensing bridge 100. A programming angle of 30° typically gives the best angle accuracy, but this can vary with other details of the construction of the sensor. This exact configuration that is shown in FIG. 1A is also referred to as Sweet60 programming.

A brief discussion is now provided of the operation of sensing bridge 100. The conductance of any of the branches in sensing bridge 100 is described by equations 1 and 2 below:

$$σ = {σ}_{0} ( 1 + {T}_{1} cos φ + {T}_{2} {sin}^{2} φ + {T}_{3} cos φ {sin}^{2} φ ) \qquad ( 1 )$$

$${T}_{1} = \frac{M R R}{2 + M R R} \qquad ( 2 )$$

Where σ is the conductance of the branch, σ₀ is the base (or unmodulated) conductance of the branch, φ is the external magnetic field, MRR is the magnetoresistance ratio of each of the branch, T₁ is the coefficient of the fundamental harmonic component of the branch's response, T₂ is the coefficient of the second harmonic component of the branch's response, T₃ is the coefficient of the third harmonic component of the branch's response. The base resistance of the branch is the resistance of the branch when no external magnetic field is on the branch. The magnetoresistance ratio of the branch is equal to the difference between the maximum and minimum resistance of the branch divided by the minimum resistance ((Rmax−Rmin)/Rmin).

The angle error of sensing bridge 100 is described by equation 3 below:

$$A E \approx \frac{1}{4} ( {T}_{2} - {T}_{3} / {T}_{1} ) ( 1 - 2 cos 2 δ ) sin 4 φ \qquad ( 3 )$$

Where AE is angle error, δ is the programming angle of sensing bridge 110. In the present example, AE vanishes at δ=30°. When T₂=T₃=0, AE=0 for any programming angle δ, and the output of sensing bridge 100 (i.e., VOUT1+VOUT2) approaches cos φ.

FIG. 1B illustrates a sensing bridge 120 that is arranged with a Series Composite configuration. The sensing bridge includes two half-bridge circuits (121 and 125) arranged in parallel between a voltage source and ground. Half-bridge 121 is made up of branches 133 and 135, while half-bridge 125 includes branches 137 and 139. Branch 133 connects to branch 135 at node 127, whereas branch 137 connects to branch 139 at node 129. The output signals, VOUT1 and VOUT2, are taken from nodes 127 and 129, respectively. Notably, there is a 180-degree phase offset between VOUT1 and VOUT2, which is advantageous for certain safety-critical applications. However, the output from sensing bridge 120 (i.e., the signals VOUT1 and VOUT2) may also include third-order harmonics, which are typically absent in the output of sensing bridge 100.

Branch 133 includes MR elements 102 and 108, which are coupled in series. Branch 135 includes MR elements 106 and 104, also coupled in series. Specifically, MR element 102 in branch 133 is located between the voltage source and MR element 108. In branch 135, MR element 104 is positioned between MR element 106 and ground. MR elements 108 and 106 from branches 133 and 135, respectively, are coupled to node 127. Similarly, branch 137 includes MR elements 106 and 104 arranged in series, while branch 139 has MR elements 102 and 108 in series. In branch 137, MR element 106 is between the voltage source and MR element 104, while MR element 108 in branch 139 is placed between MR element 102 and ground. MR elements 104 and 102 from branches 137 and 139, respectively, are coupled to node 129.

FIG. 1B illustrates that when a sensing bridge is configured according to the Series Composite programming, it includes identical diagonally opposed branches, and the pinning directions of the MR elements in each branch are separated by 60 degrees in this example. Half of this angle (30°) is herein referred to as the “programming angle” of sensing bridge 120.

A brief discussion is now provided of the operation of sensing bridge 120. The conductance of any of the branches in sensing bridge 120 is also described by equations 1 and 2, which are discussed above. However, the angle error of sensing bridge 120 is described by equation 4 below:

$$A E \approx \frac{1}{4} {T}_{2} ( 2 - 3 cos 2 δ ) sin 4 φ \qquad ( 4 )$$

Where AE is angle error, δ is the programming angle of sensing bridge 120, T₂ is the coefficient of the second harmonic component of the branch's response, and φ is the external magnetic field, MRR is the magnetoresistance ratio of each of the branches. In the present example, AE vanishes at δ≈24.1°. When T₂=T₃=0 (perfect branches),

$$AE \approx \frac{1}{4} {( {T}_{1} sin δ )}^{2} sin 4 φ .$$

In other words, equation 4 illustrates that unlike half-bridge filter programming, composite programming has a persistent second order error if the programing angle δ is different than zero even when the basic branches do not have any higher harmonic errors.

FIG. 1C illustrates an example of a sensing bridge 140 that is configured with Parallel Composite programming. Sensing bridge 140 includes four half-bridge circuits: 161, 162, 163, and 164, which are coupled in parallel with each other between a voltage source and ground.

Half-bridge 161 includes an MR element 102 and an MR element 104, coupled in series at node 171, between the voltage source and ground. MR element 102 is positioned between node 171 and the voltage source, while MR element 104 couples node 171 to ground.

Half-bridge 162 includes an MR element 108 and an MR element 106, also coupled in series at node 172, between the voltage source and ground. MR element 108 is located between node 172 and the voltage source, and MR element 106 couples node 172 to ground.

Half-bridge 163 includes an MR element 106 and an MR element 108, coupled in series at node 173, between the voltage source and ground. MR element 106 is placed between node 173 and the voltage source, while MR element 108 couples node 173 to ground.

Half-bridge 164 includes an MR element 104 and an MR element 102, coupled in series at node 174, between the voltage source and ground. MR element 104 is positioned between node 174 and the voltage source, and MR element 102 couples node 174 to ground.

Nodes 171 and 172 are short-circuited at node 181, while nodes 173 and 174 are short-circuited at node 182. The output of sensing bridge 140 includes two signals: VOUT1 and VOUT2. Signal VOUT1 is output at node 181, and signal VOUT2 is output at node 182.

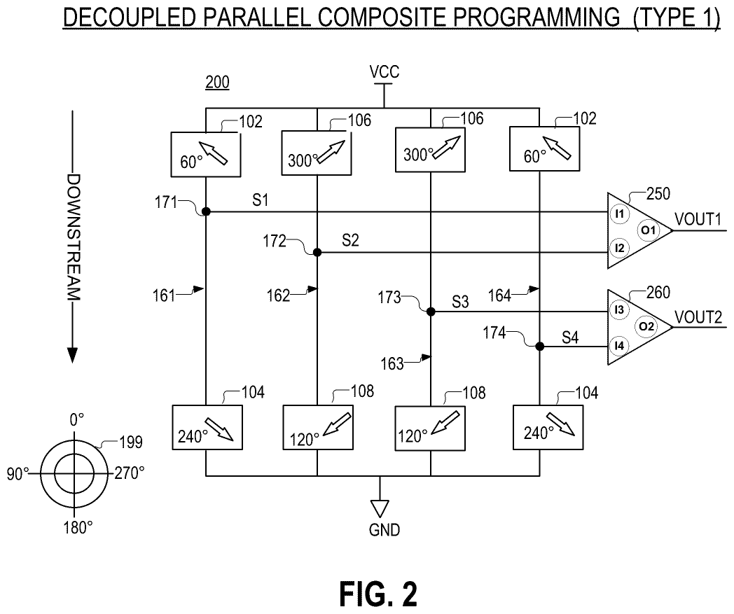

When a sensing bridge is set up according to Parallel Composite programming (as shown in FIG. 1C) or Decoupled Parallel Composite programming (illustrated in FIGS. 2-4), it includes two single-ended outputs (e.g., signals VOUT1 and VOUT2). The first single-ended output is created by using two half-bridge circuits (e.g., half-bridge circuits 161 and 162) coupled in parallel between the voltage source and ground. Each half-bridge circuit features a respective output node (e.g., nodes 171 and 172). In these half-bridge circuits, the pinning direction of the MR elements on one side of the output node is spaced 180 degrees apart from the pinning direction of the MR elements on the opposite side. Moreover, for each MR element in one of the half-bridge circuits (e.g., half-bridge 161), there exists a corresponding MR element in the other half-bridge circuit (e.g., half-bridge 162) whose pinning direction is spaced 60 degrees apart from that of first MR element.

Similarly, the second single-ended output of the sensing bridge is generated using two half-bridge circuits (e.g., half-bridge circuits 163 and 164), also coupled in parallel between the voltage source and ground. Each half-bridge circuit includes a respective output node (e.g., nodes 173 and 174). In these circuits, the pinning direction of the MR elements on one side of the output node is again spaced 180 degrees apart from the pinning direction of the MR elements on the other side. Additionally, for each MR element in one half-bridge circuit (e.g., half-bridge 163), there exists a corresponding MR element in the other half-bridge circuit (e.g., half-bridge 164) whose pinning direction is spaced 60 degrees apart from that of the first MR element. Half of this 60-degree angle is herein referred to as the “programming angle” of the sensing bridge. Although in the example of FIGS. 1C-4, the programming angle of bridges that have a parallel composite programming is 30 degrees, alternative implementations are possible in which the programming angle has a different value. A programming angle of 30° typically gives the best angle accuracy, but this can vary with other details of the construction of the sensor. In some implementations, sensing bridge 140 (or any of sensing bridges 200, 300, and 400) may have a programming angle of X/2 degrees, where X is an natural number. In such implementations, for each given MR element in sensing bridge 161 there would be a corresponding MR element in sensing bridge 162 whose pinning direction is separated by approximately X degrees from the pinning direction of the given MR element, such that the vectors of the respective pinning directions are rotated by X/2 degrees in the clockwise and counterclockwise directions from the same starting position. In the example of FIGS. 1C, 2, 3, and 4, in sensing bridges 161 and 162, MR element 108 corresponds to MR element 102, and MR element 106 corresponds to MR element 104. Similarly, for each given MR element in sensing bridge 163 there would be a corresponding MR element in sensing bridge 164 whose pinning direction is separated by approximately X degrees from the pinning direction of the given MR element, such that the vectors of the respective pinning directions are rotated by X/2 degrees in the clockwise and counterclockwise directions from the same starting position. In the example of FIGS. 1C, 2, 3, and 4, in sensing bridges 163 and 164, MR element 102 corresponds to MR element 108, and MR element 104 corresponds to MR element 106.

FIG. 2 shows an example of a sensing bridge 200 that is configured with decoupled parallel composite programming. Sensing bridge 200 is identical to sensing bridge 140 but for four differences. The first difference is that sensing bridge 200 includes differential amplifiers 250 and 260 with high impedance inputs, in addition to all components of sensing bridge 140 as shown in FIG. 1C. The second difference is in how the bridge outputs are generated. In sensing bridge 140, the output signal VOUT1 is generated by short-circuiting the output nodes 171 and 172, whereas in sensing bridge 200, the output signal VOUT1 is generated by using amplifier 250, which receives as input the signals output on nodes 171 and 172. Furthermore, in the example of sensing bridge 140, the output signal VOUT2 is generated by short-circuiting the output nodes 173 and 174, whereas in sensing bridge 200, the output signal VOUT2 is generated by using amplifier 260, which receives as input the signals output on nodes 173 and 174. Third, because the amplifier 250 needs a differential input, the positions of elements 106 and 108 in half-bridge circuit 162 are switched. Specifically, in sensing bridge 200, half bridge 162 includes MR elements 106 and 108 that are coupled in series at node 172, wherein MR element 106 is coupled between the voltage source and node 172, and MR element 108 is coupled between node 172 and ground. Fourth, in the example of FIG. 2, the positions of sensing elements 102 and 104 in half-bridge 164 are switched. As illustrated, in half bridge 164 (of sensing bridge 200), MR element 102 is coupled between the voltage source and node 174, and MR element 104 is coupled between the ground reference and node 174.

In the example of FIG. 2, a signal S1 is output on node 171 and received as input by amplifier 250; a signal S2 is output on node 172 and received as input by amplifier 250; a signal S3 is output on node 173 and received as input by amplifier 260; and a signal S4 is output on node 174 and received as input amplifier 260. Amplifier 250 generates signal VOUT1 by subtracting signal S2 from signal S1. Amplifier 260 generates signal VOUT2 by subtracting signal S4 from signal S3. The respective phases of signals S1 and S2 are 120 degrees apart. The respective phases of signals S3 and S4 are 120 degrees apart. The respective phases of signals VOUT1 and VOUT2 are 180 degrees apart. As noted above, having the phase separation between the output signals VOUT1 and VOUT2 be 180 degrees is advantageous because this makes it possible to implement various error checks that are necessary for increased fault tolerance. Moreover, compared to sensing bridge 120 (shown in FIG. 1B), the output of sensing bridge 200 shows smaller amounts of higher harmonic errors, such as less second, third, and fourth order harmonic errors.

In the example of FIG. 2, amplifier 250 includes an input terminal I1, an input terminal I2, and an output terminal O1. Signal S1 is received at input terminal I1, signal S2 is received at input terminal I2, and signal VOUT1 is output on output terminal O1. Amplifier 260 includes an input terminal I3, an input terminal I4, and an output terminal O2. Signal S3 is received at input terminal I3, signal S4 is received at input terminal I4, and signal VOUT2 is output on output terminal O2. In the example of FIG. 2, amplifiers 250 and 260 are operational amplifiers.

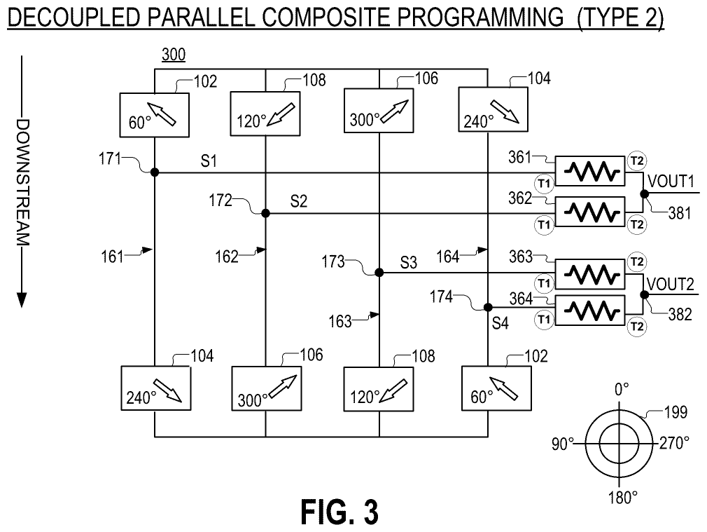

FIG. 3 shows an example of a sensing bridge 300 that is configured with decoupled parallel composite programming. Sensing bridge 300 is identical to sensing bridge 140 but for two differences. The first difference is that sensing bridge 300 includes resistors 361, 362, 363, and 364, in addition to all components of sensing bridge 140, as shown in FIG. 3. The second difference is in how the bridge outputs are generated. In sensing bridge 140, the output signal VOUT1 is generated by short-circuiting output nodes 171 and 172, whereas in sensing bridge 300, the output signal VOUT1 is generated by using resistors 361 and 362 to decouple the voltages at output nodes 171 and 172 from each other. Similarly, in sensing bridge 140, the output signal VOUT2 is generated by short-circuiting output nodes 173 and 174, whereas in sensing bridge 200 the output signal VOUT2 is generated by using resistors 363 and 364 to decouple the voltages at output nodes 173 and 174 from each other.

Each of resistors 361, 362, 363, and 364 may have a respective first terminal T1 and a respective second terminal T2. Terminal T1 of resistor 361 may be coupled to output node 171 of half-bridge 161, terminal T1 of resistor 362 may be coupled to output node 172 of half-bridge 162, and the respective terminals T2 of resistors 361 and 362 may be coupled to each other at a node 381. The output signal VOUT1 of sensing bridge 300 may be output on node 381, as shown. Terminal T1 of resistor 363 may be coupled to output node 173 of half-bridge 163, terminal T1 of resistor 364 may be coupled to output node 174 of half-bridge 164, and the respective terminals T2 of resistors 363 and 364 may be coupled to each other at a node 382. The output signal VOUT2 of sensing bridge 300 may be output on node 382, as shown. According to the present example, resistors 361, 362, 363, and 364 have the same resistance. According to the present example, terminal T2 of resistor 361 is short-circuited with terminal T2 of resistor 362 at node 381. According to the present example, terminal T2 of resistor 363 is short-circuited with terminal T2 of resistor 364 at node 382.

In the example of FIG. 3, a signal S1 is output on node 171 and received at resistor 361; a signal S2 is output on node 172 and received at resistor 362; a signal S3 is output on node 173 and received at resistor 363; and a signal S4 is output on node 174 and received at resistor 364. As noted above, the respective phases of signals S1 and S2 are 60 degrees apart. The respective phases of signals S3 and S4 are 60 degrees apart. The respective phases of signals VOUT1 and VOUT2 are 180 degrees apart. As noted above, having the phase separation between the output signals VOUT1 and VOUT2 be 180 degrees is advantageous because this makes it possible to implement various error checks that are necessary for increased fault tolerance. Moreover, compared to sensing bridge 120 (shown in FIG. 1B), the output of sensing bridge 300 shows reduced higher harmonic errors (e.g., reduced second, third, and fourth order harmonic errors, etc.).

In some respects, sensing bridge 300 permits sensor designs that are simpler and more cost-effective than designs that require integrated amplification, such as that of FIG. 2. By using resistors for signal averaging and decoupling, sensing bridge 300 enables effective harmonic filtering—particularly of the third harmonic—without relying on high-impedance op-amp inputs. This approach reduces unwanted interaction between half-bridge outputs (i.e., an interaction between nodes 171, 172, 173, and 174), minimizes angle error, and preserves the desired 180° phase relationship, making it suitable for low-complexity, high-accuracy applications.

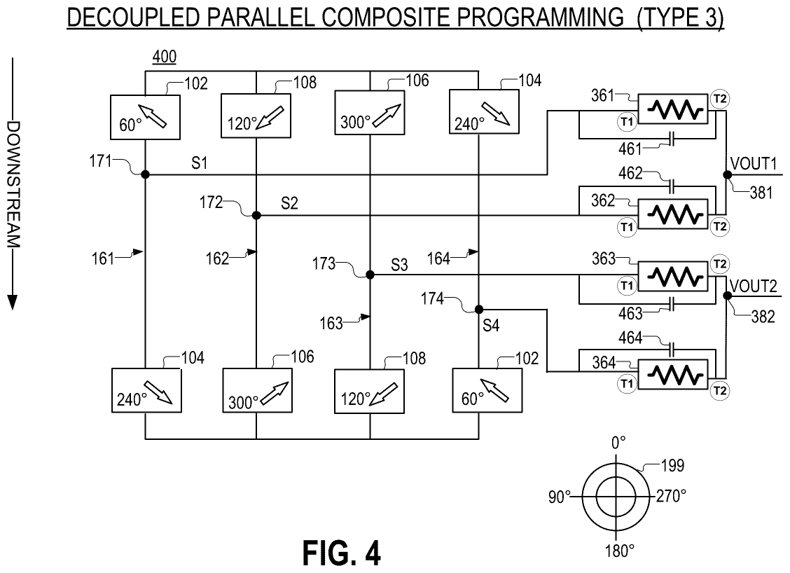

FIG. 4 shows an example of a sensing bridge 400 that is configured with decoupled parallel composite programming. Sensing bridge 400 is identical to sensing bridge 300 but for including capacitors 461, 462, 463, and 464, in addition to all components of sensing bridge 300 that are shown in FIG. 3. As shown, capacitor 461 is coupled in parallel to resistor 361, capacitor 462 is coupled in parallel to resistor 362, capacitor 463 is coupled in parallel to resistor 363, and capacitor 464 is coupled in parallel to resistor 364. According to the present example, capacitors 461, 462, 463, and 464 have the same capacitance. However, the present disclosure is not limited thereto

As noted above, the respective phases of signals S1 and S2 are 60 degrees apart. The respective phases of signals S3 and S4 are 60 degrees apart. The respective phases of signals VOUT1 and VOUT2 are 180 degrees apart. As noted above, having the phase separation between the output signals VOUT1 and VOUT2 be 180 degrees is advantageous because this makes it possible to implement various error checks that are necessary for increased fault tolerance. In some respects, compared to sensing bridge 300 (shown in FIG. 3), the output of sensing bridge 400 can show a higher bandwidth.

In the example of FIGS. 3 and 4, resistors and capacitors serve different but potentially complementary roles. The decoupling resistors 361, 362, 363, and 364 in the example of FIG. 3 are primarily used to passively decouple the outputs of half-bridges 161, 162, 163, and 164, allowing each half-bridge branch to maintain its own voltage level. This reduces unwanted harmonic mixing—especially of the third harmonic—and helps maintain angle accuracy by preserving the intended phase relationship between signals. The capacitors 461, 462, 463, and 464 may be placed parallel to decoupling resistors to address unwanted bandwidth limitations that might be inherent in the resistors. The use of capacitors 461, 462, 463, and 464 could help stabilize bandwidth. In short, resistors 361, 362, 363, and 364 (shown in FIG. 3) passively filter and decouple for signal integrity, while additional capacitors 461, 462, 463, and 464 (shown in FIG. 4) can fine-tune the frequency response and dynamic behavior of the signal path.

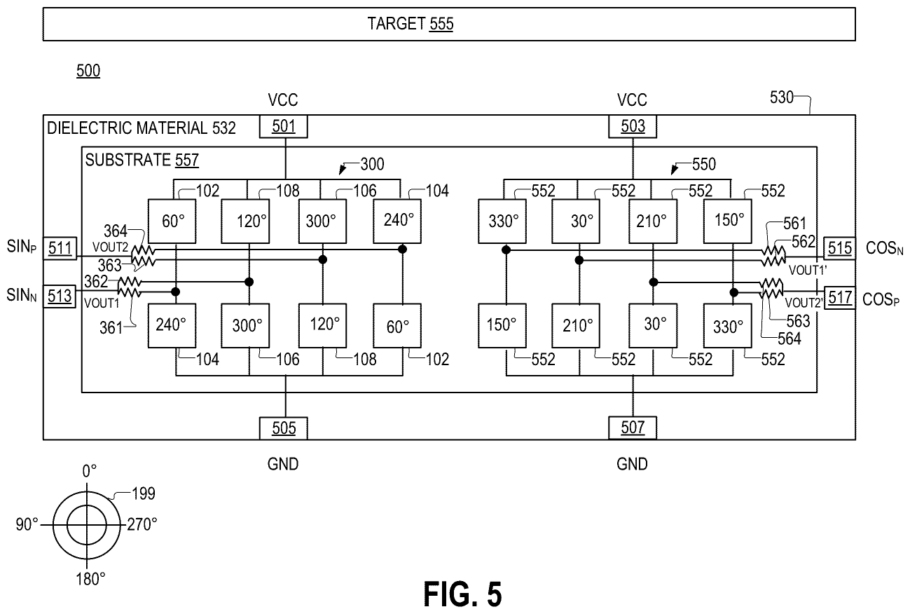

FIG. 5 illustrates an example of a system 500, which includes a position sensor 530 and a rotating target 555. The position sensor includes terminals labeled 501, 503, 505, 507, 511, 513, 515, and 517. Each terminal may include a contact pin, contact pad, or any suitable type of contact member. The substrate 557 can be a silicon substrate and/or any other suitable type of substrate.

On substrate 557, sensing bridges 300 and 550 are formed and are connected to the terminals 501-517 as shown. The substrate, along with sensing bridges 300 and 550, may be encapsulated in a layer of dielectric material 532, which can include an epoxy-based compound or any other suitable material. The layer of dielectric material 532 may form the packaging of sensor 530. The terminals 501-517 may be at least partially exposed through layer 532.

Sensing bridge 550 may include a plurality of MR elements 552 and decoupling resistors 561, 562, 563, and 564. The output of sensing bridge 550 may include signals VOUT1′ and VOUT2′, which are output from resistors 561, 562, 563, and 564. Sensing bridge 550 is identical to sensing bridge 300, but for being rotated by 90 degrees relative to sensing bridge 300. Under the nomenclature of the present disclosure, sensing bridge 550 is rotated by 90 degrees relative to sensing bridge 300 when the pinning direction of each of MR elements 552 is rotated by 90 degrees relative to the pinning direction of a corresponding one of the MR elements in sensing bridge 300. As illustrated, sensing bridge 550 and sensing bridge 300 have the same topology. Under the nomenclature of the present disclosure, a first MR element in sensing bridge 300 corresponds to a second MR element in sensing bridge 550 if both the first and second sensing element have the same position in the shared bridge topology. In the example of FIG. 5, the respective pinning direction of each of the MR elements in sensing bridge 300 and sensing bridge 550 is indicated by the text label inside the rectangle representing that MR element.

In the example depicted in FIG. 5, terminal 501 provides a voltage source for sensing bridge 300, while terminal 505 serves as a ground source for the same bridge. Terminal 503 supplies a voltage source for sensing bridge 550, and terminal 507 acts as a ground source for it. Furthermore, terminal 511 outputs the signal VOUT2 from sensing bridge 300, terminal 513 outputs VOUT1 from sensing bridge 300, terminal 515 outputs VOUT1′ from sensing bridge 550, and terminal 517 outputs VOUT2′ from sensing bridge 550. The signals VOUT1, VOUT2, VOUT1′, and VOUT2′ are generated in response to a magnetic field associated with the rotating target 555.

The rotating target 555 can include a gear illuminated by a back-bias magnetic field, a gear where a reflected magnetic field is induced, a permanent magnet, or any other suitable type of target typically used in angle-sensing applications. For example, the associated magnetic field may be a modulated back-bias field, an induced or reflected field, a field emitted by a permanent magnet, and/or any other suitable magnetic field.

According to the labels in FIG. 5, the signal output at terminal 511 is a positive sine output from sensor 530, while the signal output at terminal 513 is a negative sine output. The output at terminal 515 is a negative cosine output, and the output at terminal 517 is a positive cosine output from sensor 530. Terminals 511, 513, 515, and 517 can be coupled to external circuitry, which processes these signals to determine the angular position of the rotating target 555.

The position of target 555 may be determined in accordance with the equation of

$${T}_{p} = arc tan ( \frac{{SIN}_{P} - {SIN}_{N}}{{COS}_{P} - {COS}_{N}} ) ,$$

where T_{P} is the position of target 555, SIN_{P} is the positive sine output of sensor 530, SIN_{N} is the negative sine output of sensor 530, COS_{N} is the negative cosine output of sensor 530, and COS_{P} is the positive cosine output of sensor 530.

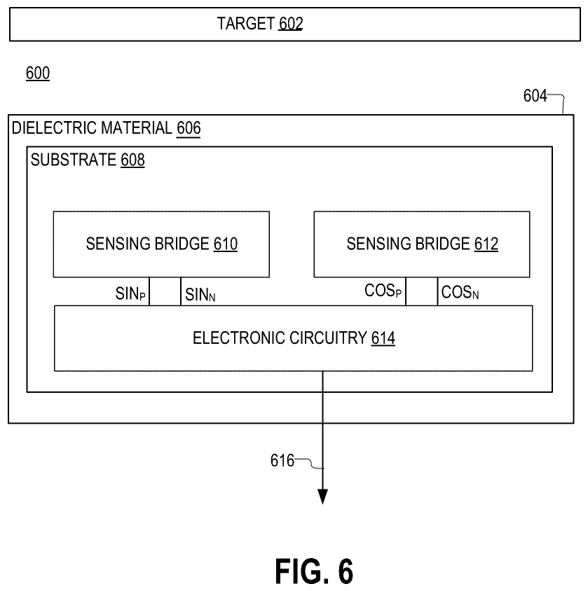

In the example shown in FIG. 6, the target 555 is a rotating target, such as a magnet with multiple pole pairs. The sensor 530 is used to measure the angular position of the target 555. However, in other possible implementations, the target 555 could be a linear magnetic scale that moves back and forth past the sensor 530 in a linear motion. This movement creates a rotating magnetic field at the location of the sensor 530. In these cases, the sensor 530 can be used to measure the linear position of the target 555. Stated succinctly, the present disclosure is not limited to using the sensing bridge architecture shown in FIGS. 2-4 in any specific type of position sensor.

FIG. 6 illustrates an example of a system 600, which includes a rotating target 602 and position sensor 604. The rotating target 602 may be the same or similar to rotating target 555 (shown in FIG. 5). The sensor 604 may be configured to sense a magnetic field that is associated with the rotating target 602 and generate an output signal 616 that is indicative of the position (e.g., angular position) of rotating target 602. The output signal 616 may be provided to external circuitry that is coupled to the sensor 604. As illustrated, sensor 606 may include a substrate 608. Formed on the substrate 608 is a sensing bridge 610, a sensing bridge 612, and electronic circuitry 614. The substrate 608, along with components 610-614, may be encapsulated in a layer of dielectric material 606. The layer of dielectric material 606 may be the same or similar to layer 532 (shown in FIG. 5), and it may be used to complete the packaging of sensor 604. Sensing bridge 610 may be the same or similar to any of sensing bridges 200, 300, and 400. Sensing bridge 612 may be identical to sensing bridge 610, but it may be rotated by 90 degrees relative to sensing bridge 610. Sensing bridge 610 may be configured to generate positive and negative sine signals and provide those signals to electronic circuitry 614. Sensing bridge 612 may generate positive and negative cosine signals and provide those signals to electronic circuitry 614. Electronic circuitry 614 may include any suitable type of digital or analog processing circuitry. For example, and without limitation, electronic circuitry 614 may include one or more amplifiers, one or more signal filters (digital or analog), one or more analog-to-digital converters, one or more analog-to-digital converters, frequency chopping circuitry, one or more modulators and/or demodulators, a general-purpose processor, a special purpose processor, and/or any other suitable type of electronic circuitry. Electronic circuitry 614 may generate the signal 616 based on the signals that are provided by sensing bridges 610 and 612. In one example, signal 616 may be generated in the manner discussed above with respect to FIG. 5. However, the present disclosure is not limited thereto. In some respects, FIGS. 5 and 6 are provided to illustrate that the sensing bridge architectures that are shown in FIGS. 2, 3, and 4 are not limited to being used in any specific sensor architecture.

In the example shown in FIG. 6, the target 602 is a rotating target, such as a magnet with multiple pole pairs. The sensor 604 is used to measure the angular position of the target 602. However, in other possible implementations, the target 602 could be a linear magnetic scale that moves back and forth past the sensor 604 in a linear motion. This movement creates a rotating magnetic field at the location of the sensor 604. In these cases, the sensor 604 can be used to measure the linear position of the target 602, and signal 616 can indicate the linear position of target 602. Stated succinctly, the present disclosure is not limited to using the sensing bridge architecture shown in FIGS. 2-4 in any specific type of position sensor.

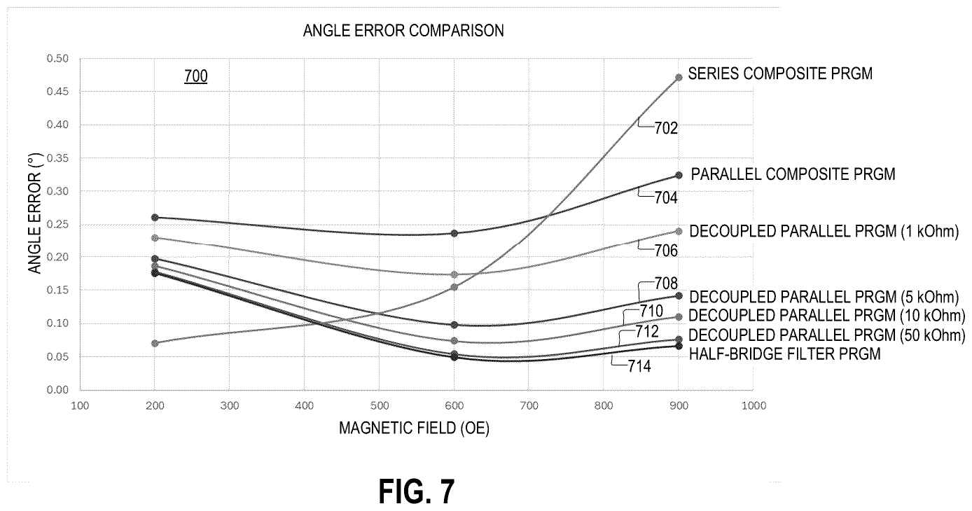

FIG. 7 is a graph (700) displaying the results of a simulation conducted on various sensing bridge architectures, including sensing bridge 300, sensing bridge 100, sensing bridge 120, and sensing bridge 140. The simulation was performed using the SPICE™ software. In this simulation, all sensing bridge instances utilized identical sets of MR elements.

The X-axis of graph 700 represents the external magnetic field measured by the simulated sensing bridges, while the Y-axis indicates the angle error for each sensing bridge instance. In essence, graph 700 illustrates how the angle error of different sensing bridge architectures varies with the strength of the magnetic field being sensed.

Graph 700 includes curves 702 to 714. Curve 702 denotes the angle error for sensing bridge 120, while curve 704 represents the angle error for sensing bridge 140. Curve 714 corresponds to the angle error for sensing bridge 100, which uses half-bridge filter programming.

Curve 706, represents the angle error of sensing bridge 300 when sensing bridge 300 is implemented with 1 kOhm decoupling resistors. Curve 708, represents the angle error of sensing bridge 300 when sensing bridge 300 is implemented with 5 kOhm decoupling resistors. Curve 710, represents the angle error of sensing bridge 300 when sensing bridge 300 is implemented with 10 kOhm decoupling resistors. Curve 712, represents the angle error of sensing bridge 300 when sensing bridge 30 is implemented with 50 kOhm decoupling resistors. In all instances the mean resistance of the MR elements (102, 104, 106, 108, 552) is 5 kOhm.

Together, curves 702 to 714 demonstrate that the decoupled parallel programming scheme, examples of which are shown in FIGS. 2-4, produces angle error comparable to that of the half-bridge filter programming while also achieving a 180-degree phase offset between the sensing bridge outputs-something that the half-bridge filter programming is unable to accomplish.

FIGS. 1A-6 are provided as an example only. Throughout the disclosure, like reference numerals refer to like parts. The examples provided with respect to FIGS. 1A-4 are not mutually exclusive and may be combined, modified, or adapted in various ways by those skilled in the art without departing from the scope and spirit of the invention defined by the appended claims. In the example of FIGS. 1-6, MR elements 102, 104, 106, and 108 are TMR elements. However, alternative implementations are possible in which any of MR elements 102, 104, 106, and 108 are GMR elements, AMR elements, and/or any other suitable type of magnetoresistor. In the discussion of FIGS. 1A-5, all MR elements 102 have a pinning direction of 60 degrees, all MR elements 104 have a pinning direction of 240 degrees, all MR elements 106 have a pinning direction of 300 degrees, and all MR elements 108 have a pinning direction of 120 degrees. The value of the pinning direction is approximate meaning that in some implementations the actual value of the pinning direction of any of MR elements 102-108 can vary by +/−10 degrees from the nominal value of the MR element. The present disclosure is not limited to MR elements 102-108 having any specific pinning directions. As used herein, the phrase “approximately X degrees” shall mean “within +/−10 degrees of being exactly X degrees.” For example, as used throughout the disclosure, the phrase “approximately 180 degrees” shall mean “within +/−10 degrees of being exactly 180 degrees.” Similarly, as used throughout the disclosure, the phrase “approximately 60 degrees” shall mean “within +/−10 degrees of being exactly 60 degrees.” In the example of FIGS. 2-4, each of the half-bridge circuits includes a single MR element on each side of the circuit's output node. However, alternative implementations are possible in which a different number of MR elements is present on each side of the output node. The term “output node” or “node” as used herein refers to a point of contact in a circuit. The point of contact may be a point in a conductive trace in the circuit, a contact pad, and/or any other suitable point of contact. In other words, the term “output node” may refer to a location in which electrical contact is made between two or more wires, conductive traces, or circuit component. The term “output” as used in the phrase “output node of a sensing bridge” is not intended to convey that the signal output on the output node is necessarily provided to external circuitry (i.e., circuitry that is not part of the sensor that contains the sensing bridge). The term “output” as used in the phrase “output node of a sub-circuit” is not intended to convey that the signal output on the output node is necessarily provided to external circuitry (i.e., circuitry that is not part of the sensor that contains the sub-circuit or circuitry that is not part of the sensing bridge that contains the sub-circuit). For example, a signal that is output on the output node may be provided to other components of the sensor. In the example of FIG. 2, amplifiers 250 and 260 are operational amplifiers, however the present disclosure is not limited thereto.

A magnetic-field sensing element can be, but is not limited to, a Hall Effect element a magnetoresistance element, or an inductive coil. As is known, there are different types of Hall Effect elements, for example, a vertical Hall element, and a Circular Vertical Hall (CVH) element. As is also known, there are different types of magnetoresistance elements, for example, a semiconductor magnetoresistance element such as Indium Antimonide (InSb), a giant magnetoresistance (GMR) element, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb). The phrase “set of magnetic field elements” shall mean “one or more magnetic field sensing elements”.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special-purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., an addition unit, a multiplication unit, etc.), as used throughout the disclosure may refer to hardware (e.g., an electronic circuit) that is configured to perform a function (e.g., addition or multiplication, etc.), software that is executed by at least one processor, and configured to perform the function, or a combination of hardware and software.

Also, for purposes of this description, the terms “couple,” “coupling,” “coupled,” “connect,” “connecting,” or “connected” refer to any manner known in the art or later developed in which energy or electric charge is allowed to be transferred between two or more elements, and the interposition of one or more additional elements is contemplated, although not required. Conversely, the terms “directly coupled,” “directly connected,” etc., imply the absence of such additional elements. Like reference numerals refer to like elements.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A sensor, comprising:
a first sub-circuit including a first magnetoresistance (MR) element and a second MR element, the first MR element and the second MR element having respective pinning directions that are separated by approximately 180 degrees, the first sub-circuit including a first output node that is situated between the first MR element and the second MR element;
a second sub-circuit including a third MR element and a fourth MR element, the third MR element and the fourth MR element having respective pinning directions that are separated by approximately 180 degrees, the second sub-circuit including a second output node that is situated between the third MR element and the fourth MR element;
a third sub-circuit including a fifth MR element and a sixth MR element, the fifth MR element and the sixth MR element having respective pinning directions that are separated by approximately 180 degrees, the third sub-circuit including a third output node that is situated between the fifth MR element and the sixth MR element;
a fourth sub-circuit including a seventh MR element and an eighth MR element, the seventh MR element and the eighth MR element having respective pinning directions that are separated by approximately 180 degrees, the fourth sub-circuit including a fourth output node that is situated between the seventh MR element and the eighth MR element;
a first amplifier having a first input terminal and a second input terminal, the first input terminal being coupled to the first output node of the first sub-circuit, the second input terminal being coupled to the second output node of the second sub-circuit, the first amplifier being configured to generate a first output signal; and
a second amplifier having a third input terminal and a fourth input terminal, the third input terminal being coupled to the third output node of the third sub-circuit, the fourth input terminal being coupled to the fourth output node of the fourth sub-circuit, the second amplifier being configured to generate a second output signal,
wherein the first sub-circuit, the second sub-circuit, the third sub-circuit, and the fourth sub-circuit are coupled in parallel with each other.

2. The sensor of claim 1, wherein:
the first MR element and the fourth MR element are diagonally opposed and have respective pinning directions that are separated by approximately 60 degrees,
the third MR element and the fourth MR element are diagonally opposed and have respective pinning directions that are separated by approximately 60 degrees,
the fifth MR element and the eighth MR element are diagonally opposed and have respective pinning directions that are separated by approximately 60 degrees, and
the sixth MR element and the seventh MR element are diagonally opposed and have respective pinning directions that are separated by approximately 60 degrees.

3. The sensor of claim 1, wherein:
the first sub-circuit includes a first half-bridge circuit;
the second sub-circuit includes a second half-bridge circuit;
the third sub-circuit includes a third half-bridge circuit; and
the fourth sub-circuit includes a fourth half-bridge circuit.

4. The sensor of claim 1, wherein each of the first, second, third, fourth, fifth, sixth, seventh, and eighth MR elements includes a tunneling magnetoresistance (TMR) element.

5. The sensor of claim 1, wherein:
the first amplifier is configured to generate the first output signal by subtracting a first signal that is output on the first output node from a second signal that is output on the second output node; and
the second amplifier is configured to generate the second output signal by subtracting a third signal that is output on the third output node from a fourth signal that is output on the fourth output node.

6. The sensor of claim 1, wherein the first sub-circuit, the second sub-circuit, the third sub-circuit, and the fourth sub-circuit are part of a first sensing bridge, the sensor further comprising:
a second sensing bridge having a same programming as the first sensing bridge, the second sensing bridge being rotated by approximately 90 degrees relative to the first sensing bridge, the second sensing bridge being arranged to generate a third output signal and a fourth output signal.

7. The sensor of claim 6, wherein:
the first, second, third, and fourth output signals are generated in response to a magnetic field that is associated with a moving target, and
the first, second, third, and fourth output signals are indicative of a position of the moving target.

8. A sensor, comprising:
a first sub-circuit including a first magnetoresistance (MR) element and a second MR element, the first MR element and the second MR element having respective pinning directions that are separated by approximately 180 degrees, the first sub-circuit including a first output node that is situated between the first MR element and the second MR element;
a second sub-circuit including a third MR element and a fourth MR element, the third MR element and the fourth MR element having respective pinning directions that are separated by approximately 180 degrees, the second sub-circuit including a second output node that is situated between the third MR element and the fourth MR element;
a third sub-circuit including a fifth MR element and a sixth MR element, the fifth MR element and the sixth MR element having respective pinning directions that are separated by approximately 180 degrees, the third sub-circuit including a third output node that is situated between the fifth MR element and the sixth MR element;
a fourth sub-circuit including a seventh MR element and an eighth MR element, the seventh MR element and the eighth MR element having respective pinning directions that are separated by approximately 180 degrees, the fourth sub-circuit including a fourth output node that is situated between the seventh MR element and the eighth MR element;
a first resistor having a first terminal and a second terminal, the first terminal being coupled to the first output node of the first sub-circuit, the second terminal being coupled to a fifth output node;
a second resistor having a third terminal and a fourth terminal, the third terminal being coupled to the second output node of the second sub-circuit, the fourth terminal being coupled to the fifth output node;
a third resistor having a fifth terminal and a sixth terminal, the fifth terminal being coupled to the third output node of the third sub-circuit, the sixth terminal being coupled to a sixth output node; and
a fourth resistor having a seventh terminal and an eighth terminal, the seventh terminal being coupled to the fourth output node of the fourth sub-circuit, the eighth terminal being coupled to the sixth output node;
wherein the first sub-circuit, the second sub-circuit, the third sub-circuit, and the fourth sub-circuit are coupled in parallel with each other and arranged to form a first sensing bridge, and
wherein a first output signal of the first sensing bridge is output on the fifth output node, and a second output signal of the first sensing bridge is output on the sixth output node.

9. The sensor of claim 8, wherein:
the first MR element is coupled between a source and the first output node, the third MR element is coupled between the source and the second output node, and the first and third MR elements have respective pinning directions that are separated by approximately X degrees;
the second MR element is coupled between ground and the first output node, the fourth MR element is coupled between the ground and the second output node, and the second and fourth MR elements have respective pinning directions that are separated by approximately X degrees;
the fifth MR element is coupled between the source and the third output node, the seventh MR element is coupled between the source and the fourth output node, and the fifth and seventh MR elements have respective pinning directions that are separated by approximately X degrees;
the sixth MR element is coupled between the ground and the third output node, the eighth MR element is coupled between the ground and the fourth output node, and the sixth and eighth MR elements have respective pinning directions that are separated by approximately X degrees; and
X is an natural number.

10. The sensor of claim 8, wherein:
the first sub-circuit includes a first half-bridge circuit;
the second sub-circuit includes a second half-bridge circuit;
the third sub-circuit includes a third half-bridge circuit; and
the fourth sub-circuit includes a fourth half-bridge circuit.

11. The sensor of claim 8, wherein each of the first, second, third, fourth, fifth, sixth, seventh, and eighth MR elements includes a tunneling magnetoresistance (TMR) element.

12. The sensor of claim 8, wherein:
the second terminal of the first resistor is short-circuited at the fifth output node to the fourth terminal of the second resistor; and
the sixth terminal of the third resistor is short-circuited at the sixth output node to the eighth terminal of the fourth resistor.

13. The sensor of claim 8, further comprising a second sensing bridge having a same programming as the first sensing bridge, the second sensing bridge being rotated by approximately 90 degrees relative to the first sensing bridge, the second sensing bridge being arranged to generate a third output signal and a fourth output signal.

14. The sensor of claim 13, wherein:
the first, second, third, and fourth output signals are generated in response to a magnetic field that is associated with a moving target, and
the first, second, third, and fourth output signals are indicative of a position of the moving target.

15. A sensor, comprising:
a first sub-circuit including a first magnetoresistance (MR) element and a second MR element, the first MR element and the second MR element having respective pinning directions that are separated by approximately 180 degrees, the first sub-circuit including a first output node that is situated between the first MR element and the second MR element;
a second sub-circuit including a third MR element and a fourth MR element, the third MR element and the fourth MR element having respective pinning directions that are separated by approximately 180 degrees, the second sub-circuit including a second output node that is situated between the third MR element and the fourth MR element;
a third sub-circuit including a fifth MR element and a sixth MR element, the fifth MR element and the sixth MR element having respective pinning directions that are separated by approximately 180 degrees, the third sub-circuit including a third output node that is situated between the fifth MR element and the sixth MR element;
a fourth sub-circuit including a seventh MR element and an eighth MR element, the seventh MR element and the eighth MR element having respective pinning directions that are separated by approximately 180 degrees, the fourth sub-circuit including a fourth output node that is situated between the seventh MR element and the eighth MR element;
a first resistor and a first capacitor, the first resistor having a first terminal and a second terminal, the first terminal being coupled to the first output node of the first sub-circuit, the second terminal being coupled to a fifth output node, the first capacitor being coupled in parallel with the first resistor;
a second resistor and a second capacitor, the second resistor having a third terminal and a fourth terminal, the third terminal being coupled to the second output node of the second sub-circuit, the fourth terminal being coupled to the fifth output node, the second capacitor being coupled in parallel with the second resistor;
a third resistor and a third capacitor, the third resistor having a fifth terminal and a sixth terminal, the fifth terminal being coupled to the third output node of the third sub-circuit, the sixth terminal being coupled to a sixth output node, the third capacitor being coupled in parallel with the third resistor; and
a fourth resistor and a fourth capacitor, the fourth resistor having a seventh terminal and an eighth terminal, the seventh terminal being coupled to the fourth output node of the fourth sub-circuit, the eighth terminal being coupled to the sixth output node, the fourth capacitor being coupled in parallel with the fourth resistor;
wherein the first sub-circuit, the second sub-circuit, the third sub-circuit, and the fourth sub-circuit are coupled in parallel with each other and arranged to form a first sensing bridge, and
wherein a first output signal of the first sensing bridge is output on the fifth output node, and a second output signal of the first sensing bridge is output on the sixth output node.

16. The sensor of claim 15, wherein:
the first MR element is coupled between a source and the first output node, the third MR element is coupled between the source and the second output node, and the first and third MR elements have respective pinning directions that are separated by approximately X degrees;
the second MR element is coupled between ground and the first output node, the fourth MR element is coupled between the ground and the second output node, and the second and fourth MR elements have respective pinning directions that are separated by approximately X degrees;
the fifth MR element is coupled between the source and the third output node, the seventh MR element is coupled between the source and the fourth output node, and the fifth and seventh MR elements have respective pinning directions that are separated by approximately X degrees;
the sixth MR element is coupled between the ground and the third output node, the eighth MR element is coupled between the ground and the fourth output node, and the sixth and eighth MR elements have respective pinning directions that are separated by approximately X degrees; and
X is an natural number.

17. The sensor of claim 15, wherein:
the first sub-circuit includes a first half-bridge circuit;
the second sub-circuit includes a second half-bridge circuit;
the third sub-circuit includes a third half-bridge circuit; and
the fourth sub-circuit includes a fourth half-bridge circuit.

18. The sensor of claim 15, wherein each of the first, second, third, fourth, fifth, sixth, seventh, and eighth MR elements includes a tunneling magnetoresistance (TMR) element.

19. The sensor of claim 15, further comprising a second sensing bridge having a same programming as the first sensing bridge, the second sensing bridge being rotated by approximately 90 degrees relative to the first sensing bridge, the second sensing bridge being arranged to generate a third output signal and a fourth output signal.

20. The sensor of claim 15, wherein:
the first, second, third, and fourth output signals are generated in response to a magnetic field that is associated with a moving target, and
the first, second, third, and fourth output signals are indicative of a position of the moving target.
